(19) United States
(12) Patent Application Publication
(10) Pub. No.: US 2009/0001481 A1
(43) Pub. Date: Jan. 1, 2009

(54) DIGITAL CIRCUITS HAVING ADDITIONAL CAPACITORS FOR ADDITIONAL STABILITY

(76) Inventors: Ethan Harrison Cannon, Essex Junction, VT (US); Toshiharu Furukawa, Essex Junction, VT (US); David Vaclav Horak, Essex Junction, VT (US); Jack A. Mandelman, Flat Rock, NC (US); William Robert Tonti, Essex Junction, VT (US)

Correspondence Address: SCHMEISER, OLSEN & WATTS, 22 CENTURY HILL DRIVE, SUITE 302, LATHAM, NY, 12110, US

(21) Appl. No.: 11/768,270

(22) Filed: Jun. 26, 2007

(51) Int. Cl. H01L 27/105; H01L 21/8238

(52) U.S. Cl. 257/390; 438/128; 257/E27.081; 257/E21.642

(57) ABSTRACT

A semiconductor structure and a method for forming the same. The semiconductor structure includes (a) a semiconductor substrate, (b) a shallow trench isolation (STI) region on the semiconductor substrate, and (c) a first semiconductor transistor on the semiconductor substrate. The first semiconductor transistor includes (I) a first source/drain region, (ii) a second source/drain region, and (iii) a first gate electrode region. The first and second source/drain regions are doped with a same doping polarity. The semiconductor structure further includes a first doped region in the semiconductor substrate. The first doped region is on a first side wall and a bottom wall of the STI region. The first doped region is in direct physical contact with the second source/drain region. The first doped region and the second source/drain region are doped with a same doping polarity.

### FIELD OF THE INVENTION

The present invention relates generally to digital circuits and more particularly to digital circuits having additional parasitic capacitors for additional stability.

### BACKGROUND OF THE INVENTION

A conventional digital circuit may undesirably change from one state to another due to the impact of external particles. Therefore, there is a need for a semiconductor structure (and a method for forming the same) in which it is more difficult for the semiconductor structure to change from one state to another due to the impact of external particles.

### SUMMARY OF THE INVENTION

The present invention provides semiconductor structure, comprising (a) a semiconductor substrate; (b) a shallow trench isolation (STI) region on the semiconductor substrate; (c) a first semiconductor transistor on the semiconductor substrate, wherein the first semiconductor transistor comprises (i) a first source/drain region, (ii) a second source/drain region, and (iii) a first gate electrode region, and wherein the first and second source/drain regions are doped with a first doping polarity; and (d) a first doped region in the semiconductor substrate, wherein the first doped region is on a first side wall and a bottom wall of the STI region, wherein the first doped region is in direct physical contact with the second source/drain region, and wherein the first doped region is doped with the first doping polarity.

The present invention provides a semiconductor structure (and a method for forming the same) in which it is more difficult for the semiconductor structure to change from one state to another due to the impact of external particles.

### BRIEF DESCRIPTION OF THE DRAWINGS

FIG. 1 shows a circuit diagram of a digital circuit, in accordance with embodiments of the present invention.

FIG. 2A shows a top-down view of the digital circuit (whose circuit diagram is shown in FIG. 1), in accordance with embodiments of the present invention.

FIG. 2B shows a cross-section view of the digital circuit of FIG. 2A along a line, in accordance with embodiments of the present invention.

FIGS. 3A-3P show cross-section views used to illustrate a fabrication process of the digital circuit of FIG. 2B, in accordance with embodiments of the present invention.

FIG. 4 shows a circuit diagram of another digital circuit, in accordance with embodiments of the present invention.

FIG. 5A shows a top-down view of the digital circuit (whose circuit diagram is shown in FIG. 4), in accordance with embodiments of the present invention.

FIG. 5B shows a cross-section view of the digital circuit of FIG. 5A along a line, in accordance with embodiments of the present invention.

FIGS. 6A-6L show cross-section views used to illustrate a fabrication process of the digital circuit of FIG. 5B, in accordance with embodiments of the present invention.

FIGS. 7A-7E show cross-section views used to illustrate an alternative fabrication process, in accordance with embodiments of the present invention.

### DETAILED DESCRIPTION OF THE INVENTION

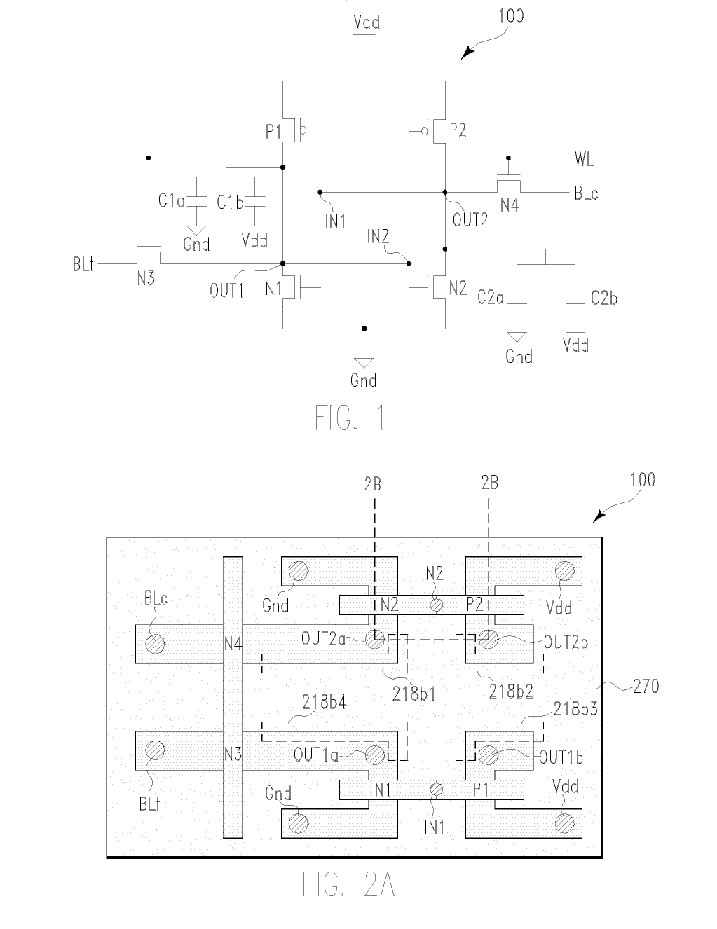

FIG. 1 shows a circuit diagram of a digital circuit 100, in accordance with embodiments of the present invention. More specifically, the digital circuit 100 comprises a PFET (p-channel field effect transistor) P1 and an NFET (n-channel field effect transistor) N1 coupled together in series between Vdd and ground. The PFET P1 and the NFET N1 constitute a first inverter P1+N1. The digital circuit 100 further comprises a PFET P2 and an NFET N2 coupled together in series between Vdd and ground. The PFET P2 and the NFET N2 constitute a second inverter P2+N2.

In one embodiment, the inverters P1+N1 and P2+N2 are cross-coupled together. More specifically, an input IN1 of the first inverter P1+N1 is electrically coupled to an output OUT2 of the second inverter P2+N2, whereas an output OUT1 of the first inverter P1+N1 is electrically coupled to an input IN2 of the second inverter P2+N2. The digital circuit 100 further comprises an NFET N3 and an NFET N4 such that (i) the output OUT1 of the first inverter P1+N1 is electrically connected to a bitline true BLt through the NFET N3 and (ii) the output OUT2 of the second inverter P2+N2 is electrically connected to a bitline complement BLc through the NFET N4. The gate electrodes of the NFETs N3 and N4 are electrically connected to a wordline WL.

In one embodiment, the digital circuit 100 further comprises capacitors C1a, C1b, C2a, and C2b. The capacitor C1a is electrically coupled between the output OUT1 and Ground, whereas the capacitor C1b is electrically coupled between the output OUT1 and Vdd. The capacitor C2a is electrically coupled between the output OUT2 and Ground, whereas the capacitor C2b is electrically coupled between the output OUT2 and Vdd. It should be noted that the digital circuit 100 constitutes an SRAM (Static Random Access Memory) cell which can store one bit (i.e., two states) of information. For instance, in a first state, the input IN1 and the output OUT2 are at logic 0 (i.e., IN1=OUT2=0) and the input IN2 and the output OUT1 are at logic 1 (i.e., IN2=OUT1=1), whereas in a second state, IN1=OUT2=1 and IN2=OUT1=0.

It should be noted that external particles impinging on the digital circuit 100 may change the digital circuit 100 from one state to another. The presence of the capacitors C1a, C1b, C2a, and C2b makes it more difficult for the digital circuit 100 to change from one state to another.

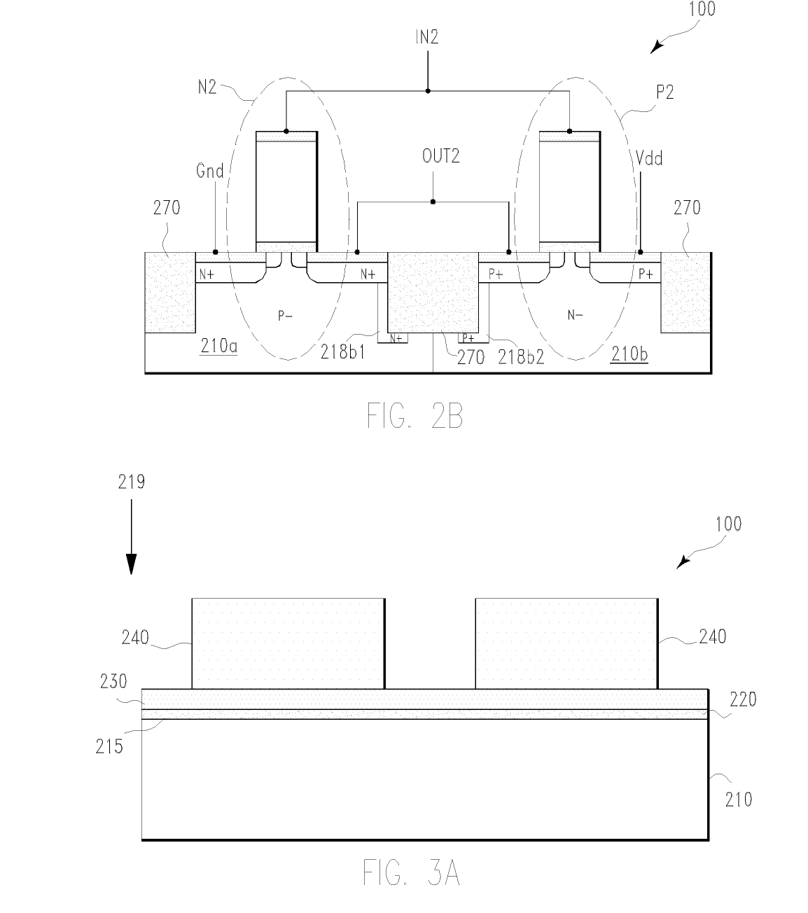

FIG. 2A shows a top-down view of the digital circuit 100 (whose circuit diagram is shown in FIG. 1), in accordance with embodiments of the present invention. A contact region OUT1a is electrically connected to a contact region OUT1b through a metal line (not shown) in an interconnect layer (not shown). It should be noted that the contact regions OUT1a and OUT1b are represented by the output OUT1 of FIG. 1. A contact region OUT2a is electrically connected to a contact region OUT2b through a metal line (not shown) in an interconnect layer (not shown). It should be noted that the contact regions OUT2a and OUT2b are represented by the output OUT2 of FIG. 1.

In one embodiment, doped regions 218b1, 218b2, 218b3, and 218b4 (the doped regions 218b1 and 218b2 are better shown in FIG. 2B) of the digital circuit 100 reside on the side walls and bottom walls of an STI (shallow trench isolation) region 270. The doped regions 218b1, 218b2, 218b3, and 218b4 are parts of the capacitors C2a, C2b, C1b, and C1a, respectively, of FIG. 1.

FIG. 2B shows a cross-section view of the digital circuit 100 of FIG. 2A along a line 2B-2B, in accordance with embodiments of the present invention. Although the twelve contact regions (e.g., the contact regions OUT1a, OUT1b, OUT2a and OUT2b, ect.) are shown in FIG. 2A, they are not shown in FIG. 2B for simplicity.

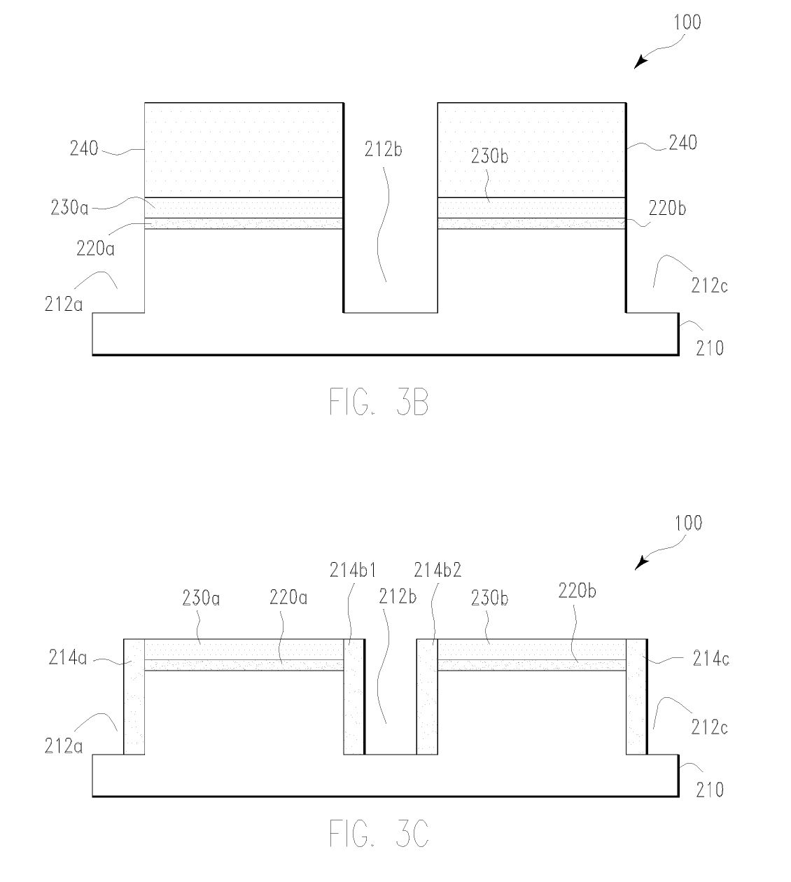

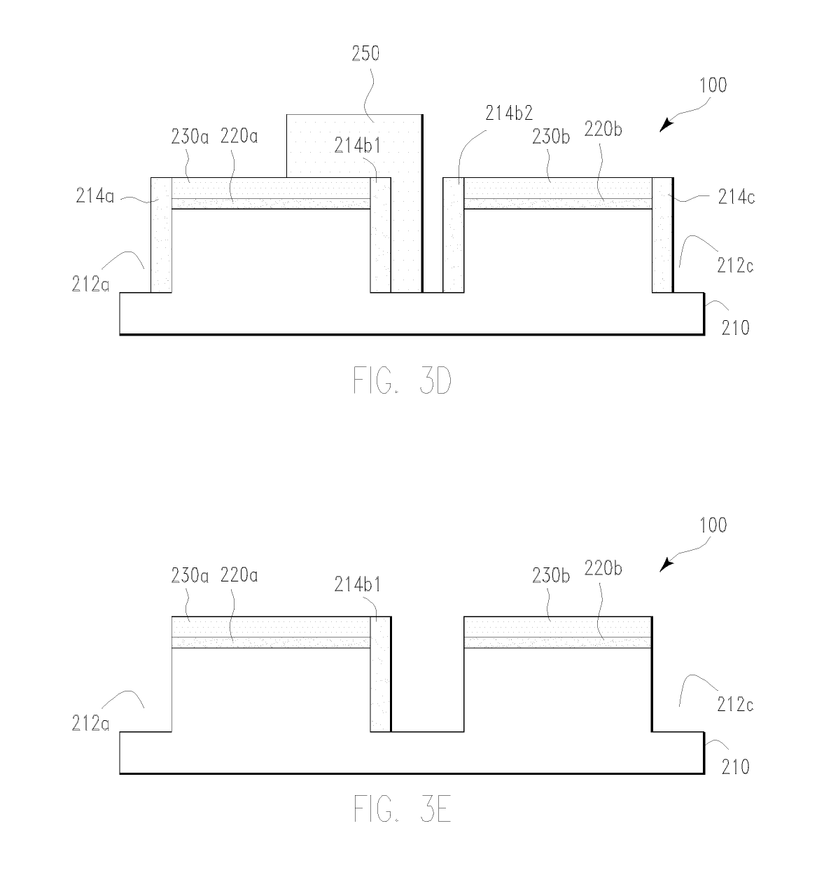

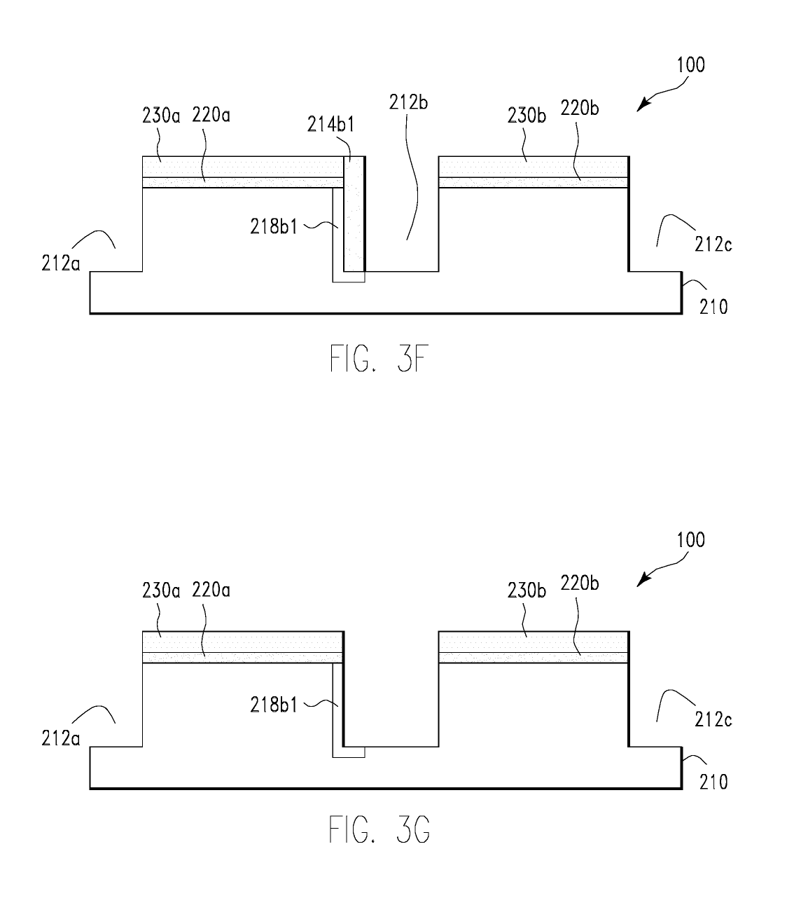

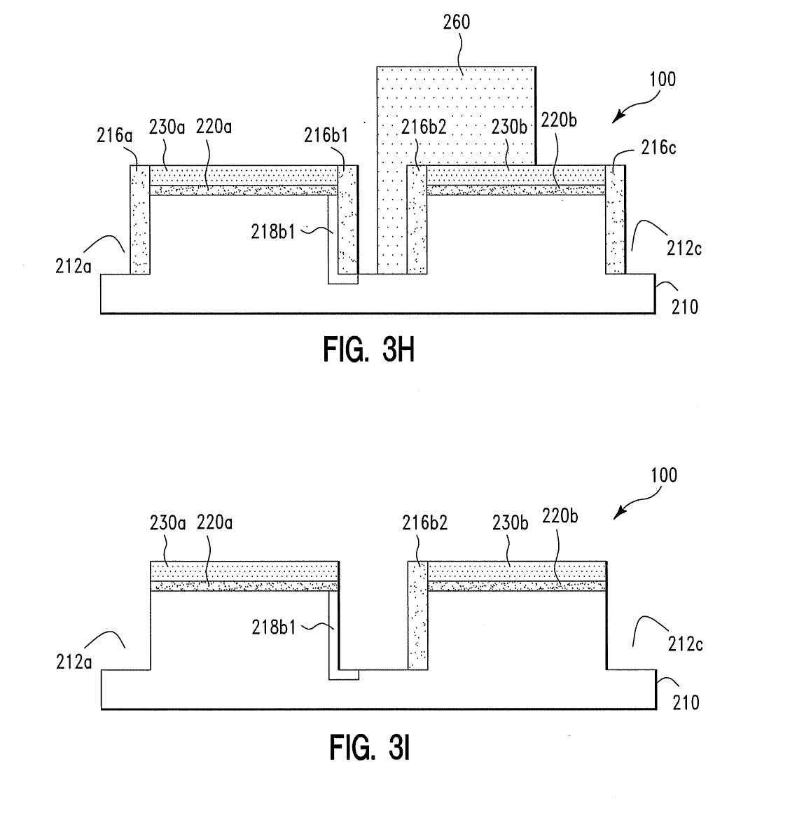

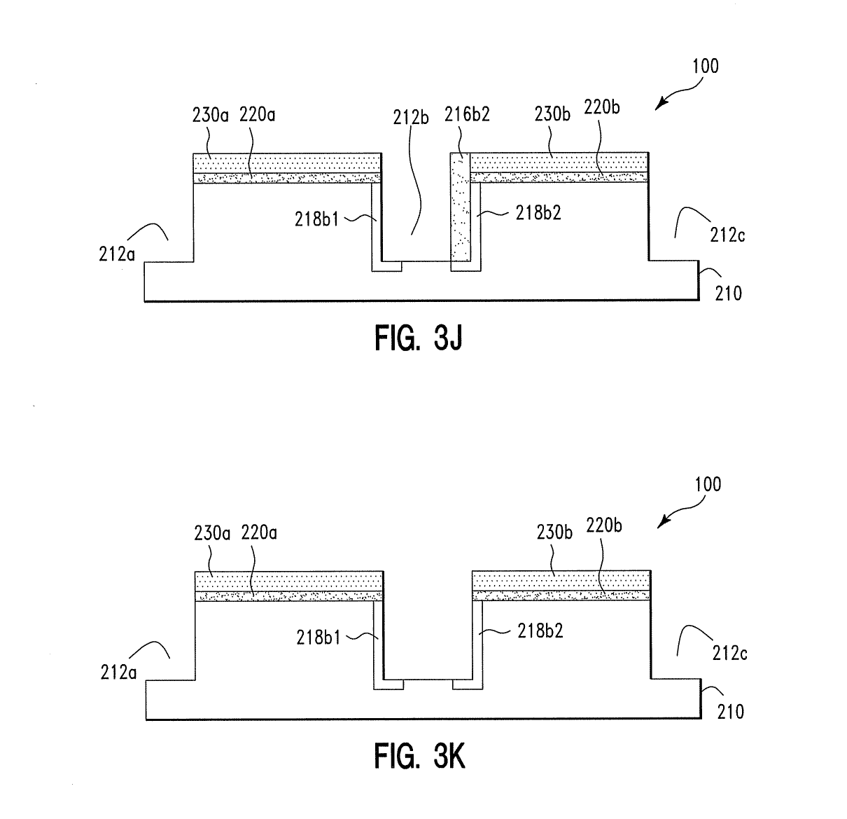

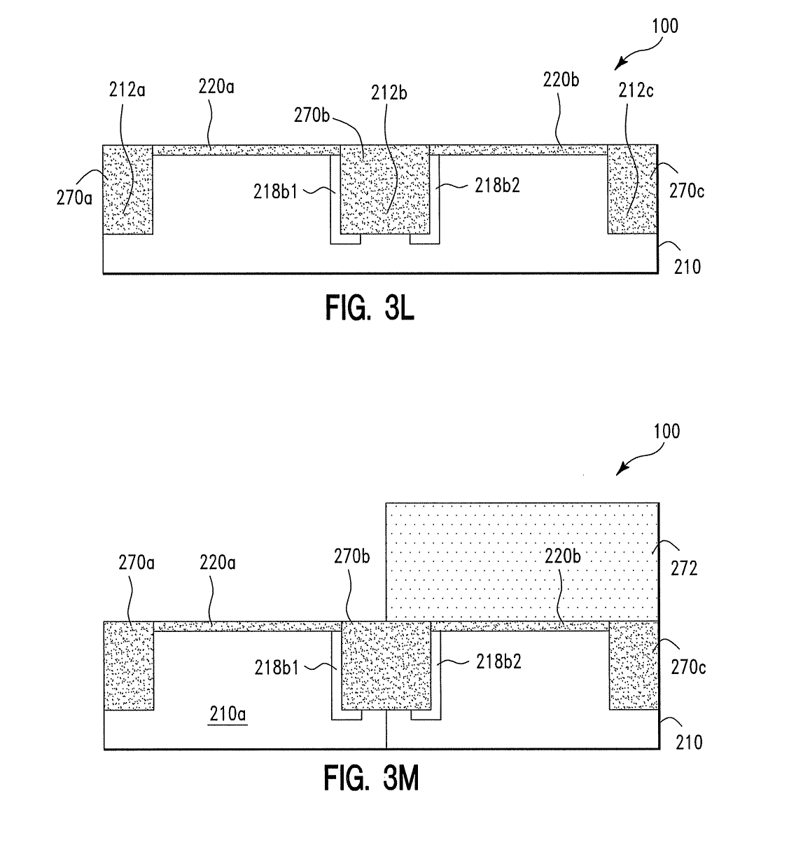

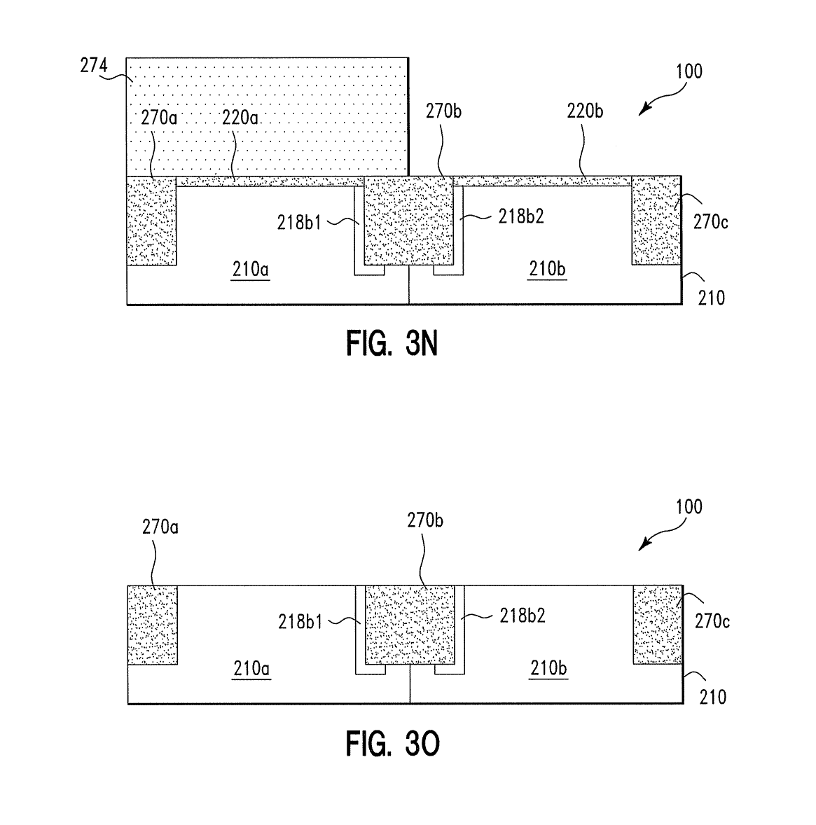

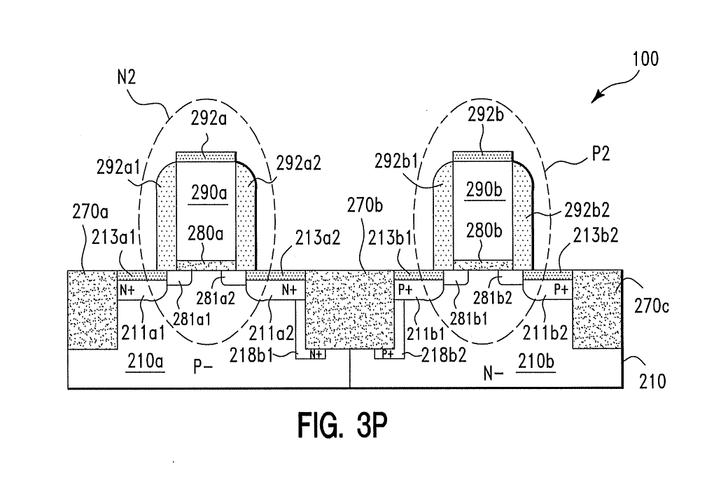

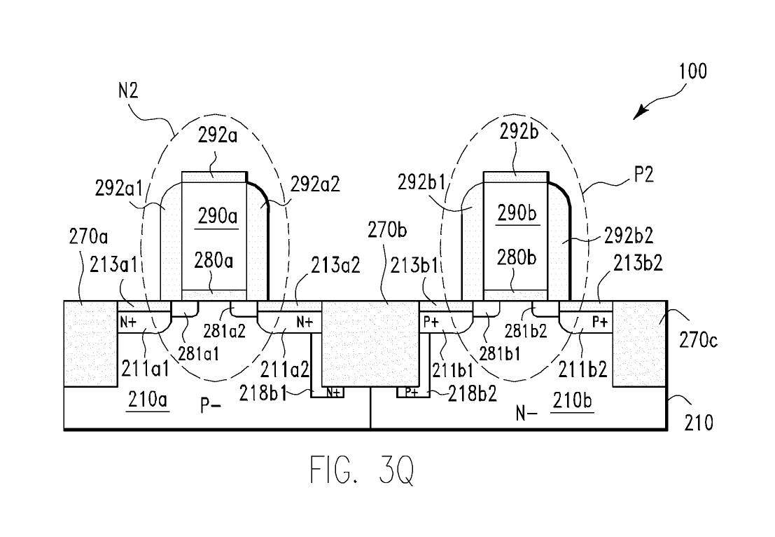

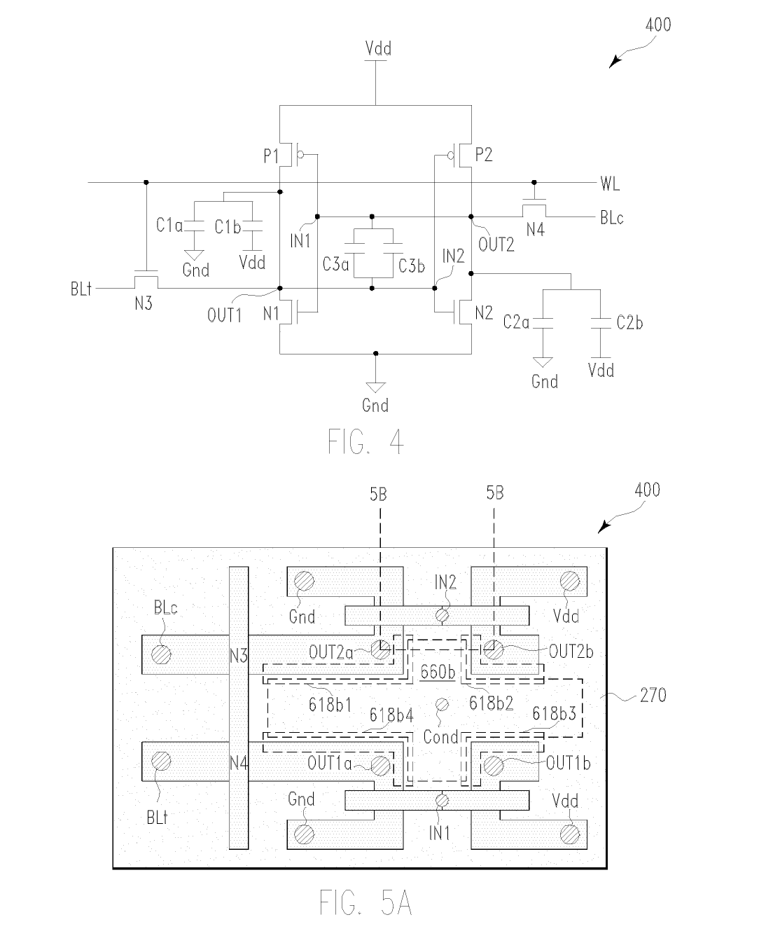

FIGS. 3A-3P show cross-section views used to illustrate a fabrication process of the digital circuit 100 of FIG. 2B, in accordance with embodiments of the present invention. More specifically, with reference to FIG. 3A, the fabrication process of the digital circuit 100 (also called structure 100) starts with a silicon substrate 210. Next, an oxide layer 220 is formed on top of the silicon substrate 210. The oxide layer 220 can comprise silicon dioxide. The oxide layer 220 can be formed by thermal oxidizing a top surface 215 of the silicon substrate 210.

Next, in one embodiment, a nitride layer 230 is formed on top of the oxide layer 220. The nitride layer 230 can be formed by CVD (Chemical Vapor Deposition) of silicon nitride on top of the oxide layer 220. Next, a patterned photoresist layer 240 is formed on top of the nitride layer 230 using a conventional method.

Next, in one embodiment, the nitride layer 230, the oxide layer 220, and the silicon substrate 210 are in turn anisotropically etched in a vertical direction 219 (i.e., the direction which is perpendicular to the top surface 215 of the silicon substrate 210) with the pattered photoresist layer 240 as a blocking mask resulting in trenches 212a, 212b, and 212c in the silicon substrate 210 of FIG. 3B.

Next, with reference to FIG. 3B, in one embodiment, the patterned photoresist layer 240 is removed. The patterned photoresist layer 240 can be removed by plasma or wet etching.

Next, with reference to FIG. 3C, ASG (arsenic silicate glass) spacer regions 214a, 214b1, 214b2, and 214c are formed on side walls of the trenches 212a, 212b, and 212c. The ASG spacer regions 214a, 214b1, 214b2, and 214c can be formed using a conventional method (e.g., by depositing a conformal ASG layer followed by directional dry etching).

Next, with reference to FIG. 3D, in one embodiment, a photoresist region 250 is formed on top of the structure 100 of FIG. 3C such that (i) the ASG spacer region 214b1 is covered by the photoresist region 250 and (ii) the ASG spacer regions 214a, 214b2, and 214c are exposed to the surrounding ambient.

Next, in one embodiment, the ASG spacer regions 214a, 214b2, and 214c are removed. The ASG spacer regions 214a, 214b2, and 214c can be removed by wet etching.

Next, in one embodiment, the photoresist region 250 is removed resulting in the structure 100 of FIG. 3E. The photoresist region 250 can be removed by plasma or wet etching.

Next, with reference to FIG. 3F, in one embodiment, the n-type doped region 218b1 is formed in the silicon substrate 210. The n-type doped region 218b1 can be formed by annealing the structure 100 of FIG. 3E resulting in arsenic atoms from the ASG spacer region 214b1 being diffused into the silicon substrate 210 resulting in the n-type doped region 218b1 on the side walls and bottom walls of the trench 212b. Next, the ASG spacer region 214b1 is removed resulting in the structure 100 of FIG. 3G. The ASG spacer region 214b1 can be removed by wet etching.

Next, with reference to FIG. 3H, in one embodiment, BSG (boron silicate glass) spacer regions 216a, 216b1, 216b2, and 216c are formed on side walls of the trenches 212a, 212b, and 212c. The BSG spacer regions 216a, 216b1, 216b2, and 216c can be formed using a conventional method (e.g., by depositing a conformal BSG layer followed by directional dry etching).

Next, in one embodiment, a photoresist region 260 is formed on top of the structure 100 such that (i) the BSG spacer region 216b2 is covered by the photoresist region 260 and (ii) the BSG spacer regions 216a, 216b1, and 216c are exposed to the surrounding ambient.

Next, in one embodiment, the BSG spacer regions 216a, 216b1, and 216c are removed. The BSG spacer regions 216a, 216b1, and 216c can be removed by wet etching.

Next, in one embodiment, the photoresist region 260 is removed resulting in the structure 100 of FIG. 31. The photoresist region 260 can be removed by wet etching.

Next, with reference to FIG. 3J, in one embodiment, the p-type doped region 218b2 is formed in the silicon substrate 210. The p-type doped region 218b2 can be formed by annealing the structure 100 of FIG. 31 resulting in boron atoms from the BSG spacer region 216b2 being diffused into the silicon substrate 210 resulting in the p-type doped region 218b2 on the side walls and bottom walls of the trench 212b. Next, the BSG spacer region 216b2 is removed resulting in the structure 100 of FIG. 3K. The BSG spacer region 216b2 can be removed by wet etching.

Next, with reference to FIG. 3L, in one embodiment, dielectric regions 270a, 270b, and 270c are formed in the trenches 212a, 212b, and 212c, respectively. The dielectric regions 270a, 270b, and 270c can be formed by CVD of silicon dioxide on top of the structure 100 followed by a CMP (Chemical Mechanical Polishing) process.

Next, in one embodiment, the nitride regions 230a and 230b (FIG. 3K) are removed. The nitride regions 230a and 230b can be removed by wet etching.

Next, with reference to FIG. 3M, in one embodiment, a P-well region 210a is formed in the silicon substrate 210. The P-well region 210a can be formed by (i) forming a photoresist region 272 on top of the trench 212c, the oxide region 220b, and a right half of the trench 212b by a conventional method and then (ii) ion implanting p-type dopants (e.g., boron atoms) into the silicon region 210 with the photoresist region 272 as a blocking mask. The P-well region 210a is lightly doped such that the dopant concentration of the P-well region 210a is lower than the dopant concentration of the n-type doped region 218b1 which is heavily doped.

Next, in one embodiment, the photoresist region 272 is removed. The photoresist region 272 can be removed by wet etching.

Next, with reference to FIG. 3N, in one embodiment, an N-well region 210b is formed in the silicon substrate 210. The N-well region 210b can be formed by (i) forming a photoresist region 274 on top of the trench 212a, the oxide region 220a, and a left half of the trench 212b by a conventional method and then (ii) ion implanting n-type dopants (e.g., arsenic atoms) into the silicon region 210 with the photoresist region 274 as a blocking mask. The N-well region 210b is lightly doped such that the dopant concentration of the N-well region 210b is lower than the dopant concentration of the p-type doped region 218b2 which is heavily doped.

Next, in one embodiment, the photoresist region 274 is removed. The photoresist region 274 can be removed by wet etching.

Next, in one embodiment, the photoresist region 274 and the oxide regions 220a and 220b are removed resulting in the structure 100 of FIG. 3O. The photoresist region 274 and the oxide regions 220a and 220b can be removed by wet etching.

Next, with reference to FIG. 3P, in one embodiment, the NFET N2 and the PFET P2 are formed on top of the P-well region 210a and the N-well region 210b of FIG. 3O, respectively. The NFET N2 and the PFET P2 can be formed by a conventional method. The NFET N2 comprises the P-well region 210a, source/drain regions 211a1 and 211a2, extension regions 281a1 and 281a2, a gate dielectric region 280a, a gate electrode region 290a, nitride spacer regions 292a1 and 292a2, and silicide regions 213a1, 213a2, and 292a. Similarly, the PFET P2 comprises the N-well region 210b, source/drain regions 211b1 and 211b2, extension regions 281b1 and 281b2, a gate dielectric region 280b, a gate electrode region 290b, nitride spacer regions 292b1 and 292b2, and silicide regions 213b1, 213b2, and 292b.

Next, in one embodiment, a dielectric layer (not shown) is formed on top of the structure 100 of FIG. 3P. Next, contact regions (including the contact regions OUT2a and OUT2b of FIG. 2A) are formed in the dielectric layer to provide electrical access to the silicide regions 213a1, 213a2, 213b1, 213b2, 292a, and 292b. It should be noted that the structure 100 of FIG. 3P is the same as the structure 100 of FIG. 2B except that the structure 100 of FIG. 3P has more details.

With reference to FIG. 3P, the source/drain region 211a2 and the n-type doped region 218b1 constitute an N+ region 211a2+218b1. The N+region 211a2+218b1 is in direct physical contact with the P-well region 210a resulting in the parasitic P-N junction capacitor C2a (FIG. 1). This is because a P-N junction can be considered a P-N junction capacitor having (i) a depletion region at the common interfacing area of the P region and the N region of the P-N junction as the capacitor dielectric and (ii) the P region and the N region on two sides of the depletion region as the two capacitor electrodes. With the presence of the n-type doped region 218b1, a common interfacing area between the N+ region 211a2+218b1 and the P-well region 201a is larger than the case in which the n-type doped region 218b1 is not present, resulting in the capacitor C2a having a higher capacitance.

Similarly, the source/drain region 211b1 and the p-type doped region 218b2 constitute a P+ region 211b1+218b2. The P+ region 211b1+218b2 is in direct physical contact with the N-well region 210b resulting in the parasitic P-N junction capacitor C2b (FIG. 1). With the presence of the p-type doped region 218b2, a common interfacing area between the P+ region 211b1+218b2 and the N-well region 210b is larger than the case in which the p-type doped region 218b2 is not present, resulting in the capacitor C2b having a higher capacitance.

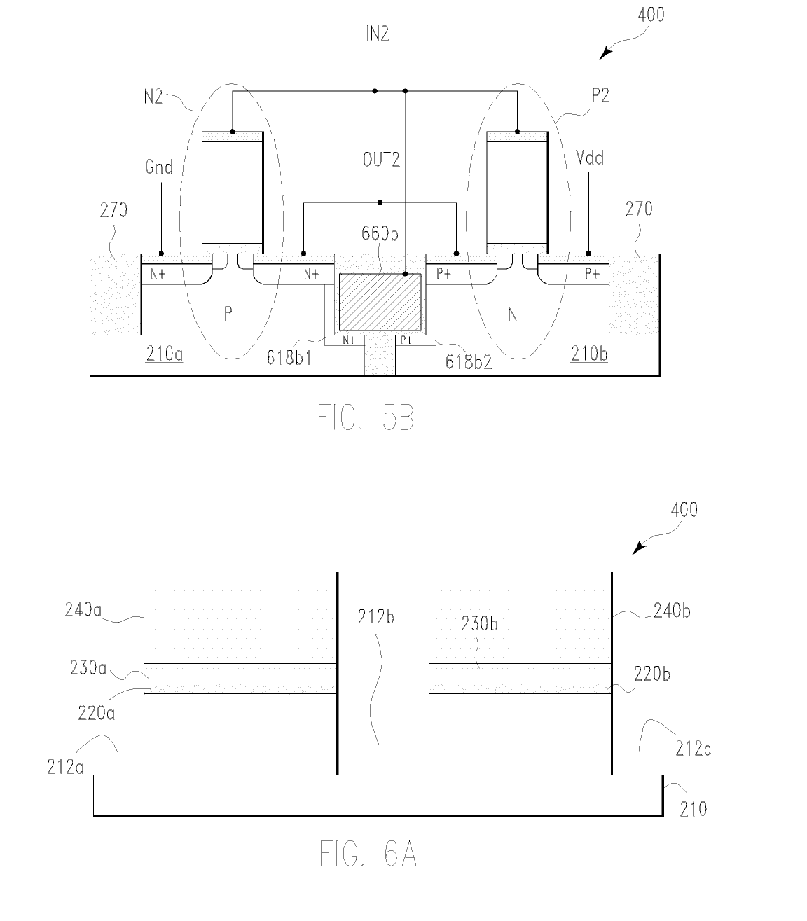

FIG. 4 shows a circuit diagram of a digital circuit 400, in accordance with embodiments of the present invention. More specifically, the digital circuit 400 is similar to the digital circuit 100 of FIG. 1 except that the digital circuit 400 further comprises capacitors C3a and C3b which are electrically connected between the input IN2 and the output OUT2. It should be noted that the digital circuit 400 constitutes an SRAM cell which can store one bit (i.e., two states) of information. The presence of the capacitors C3a and C3b makes it even more difficult for the digital circuit 400 to change from one state to another.

FIG. 5A shows a top-down view of the digital circuit 400 (whose circuit diagram is shown in FIG. 4), in accordance with embodiments of the present invention. More specifically, the digital circuit 400 of FIG. 5A is similar to the digital circuit 100 of FIG. 2A except that the digital circuit 400 further comprises a conductor region 660b. Although doped regions 618b1, 618b2, 618b3, and 618b4 are similar to the doped regions 218b1, 218b2, 218b3, and 218b4 of FIG. 2A, the doped regions 618b1, 618b2, 618b3, and 618b4 are formed differently. As a result, different reference numerals are used for these doped regions. The conductor region 660b is electrically connected to the input IN2 through a metal line (not shown) in an interconnect layer (not shown).

FIG. 5B shows a cross-section view of the digital circuit 400 of FIG. 5A along a line 5B-5B, in accordance with embodiments of the present invention. The doped region 618b1 and the conductor region 660b are two capacitor electrodes of the capacitor C3a of FIG. 4, whereas the doped region 618b2 and the conductor region 660b are two capacitor electrodes of the capacitor C3b of FIG. 4.

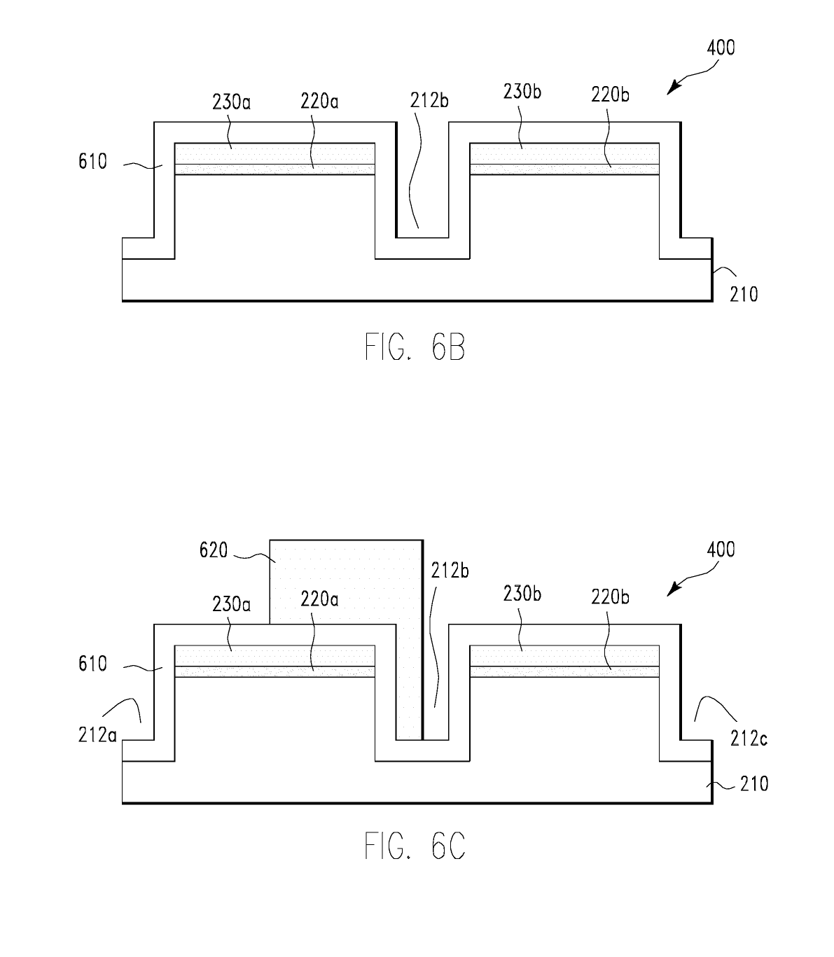

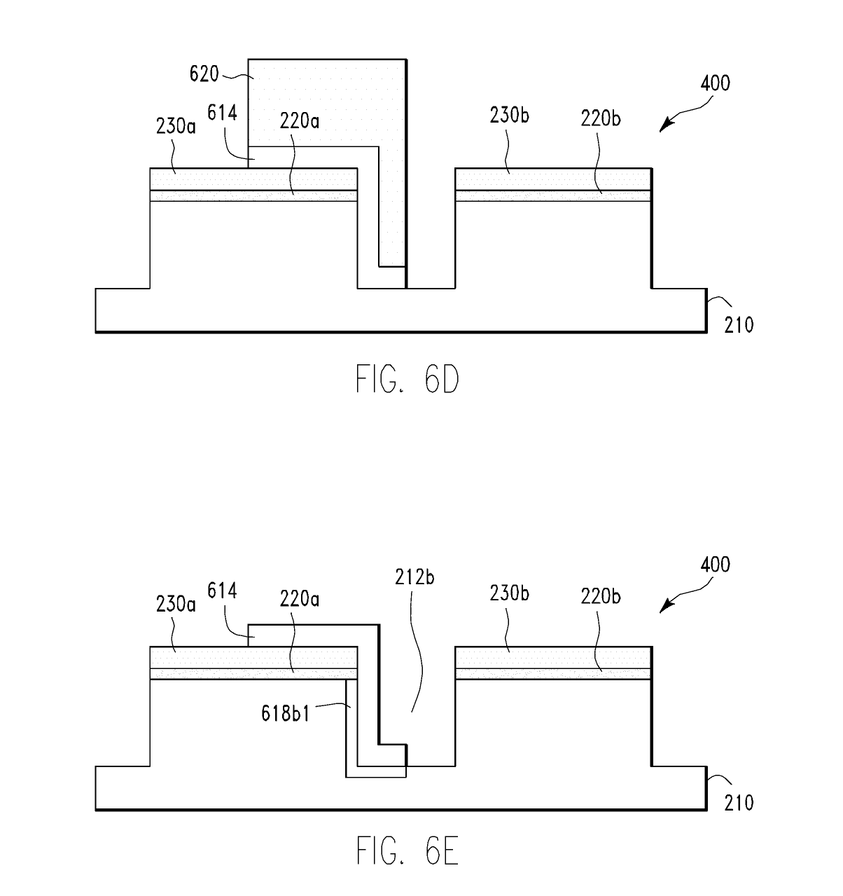

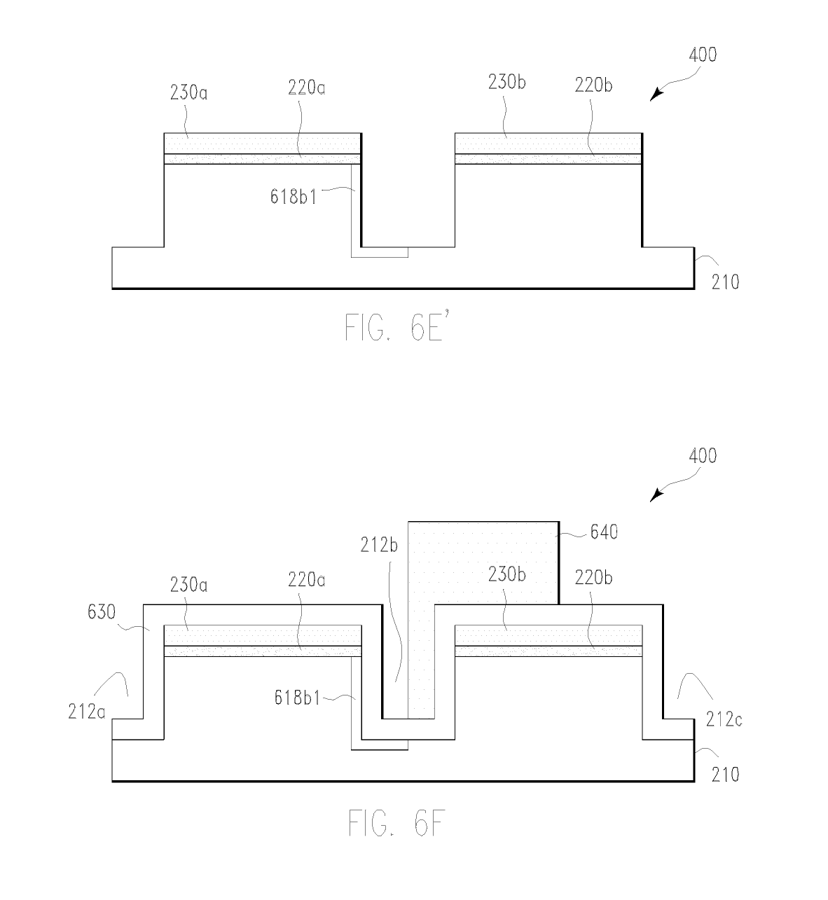

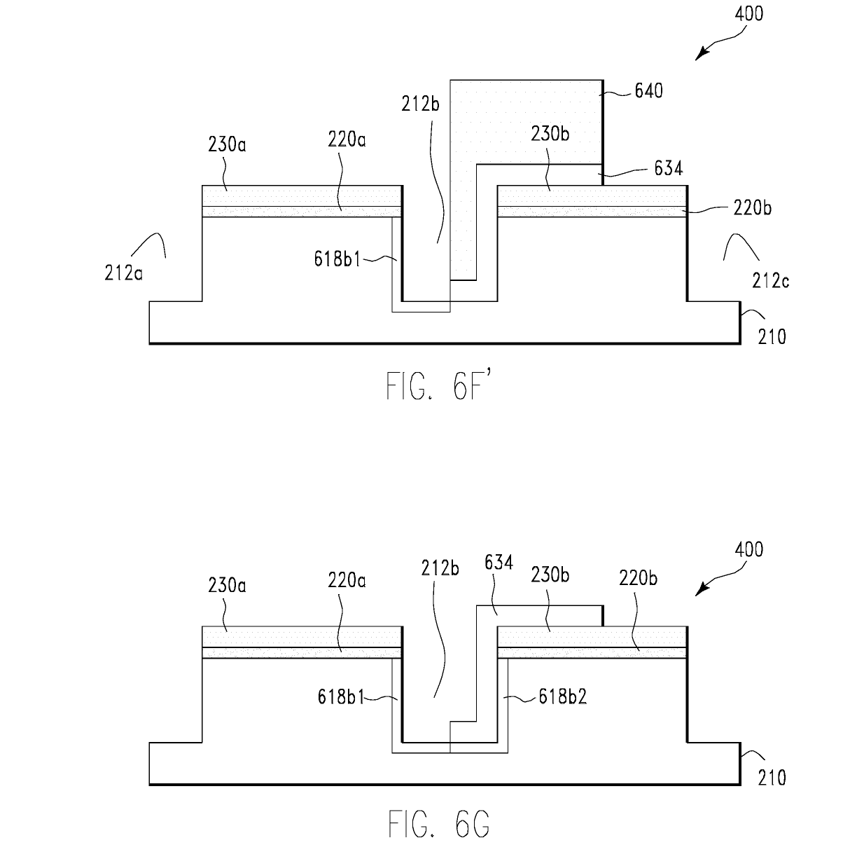

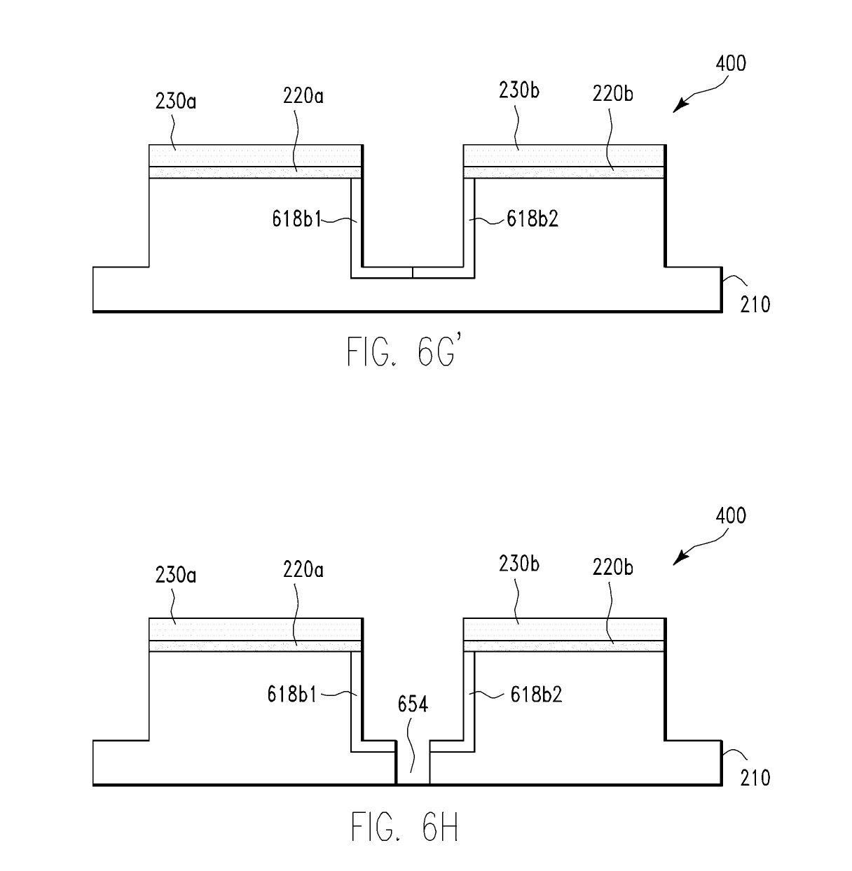

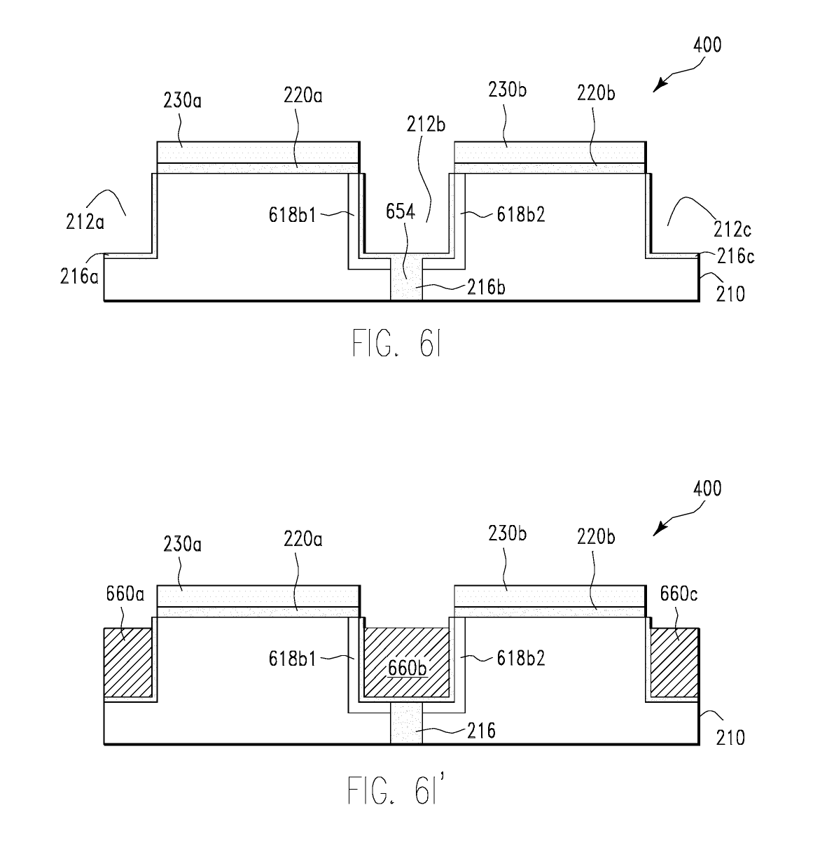

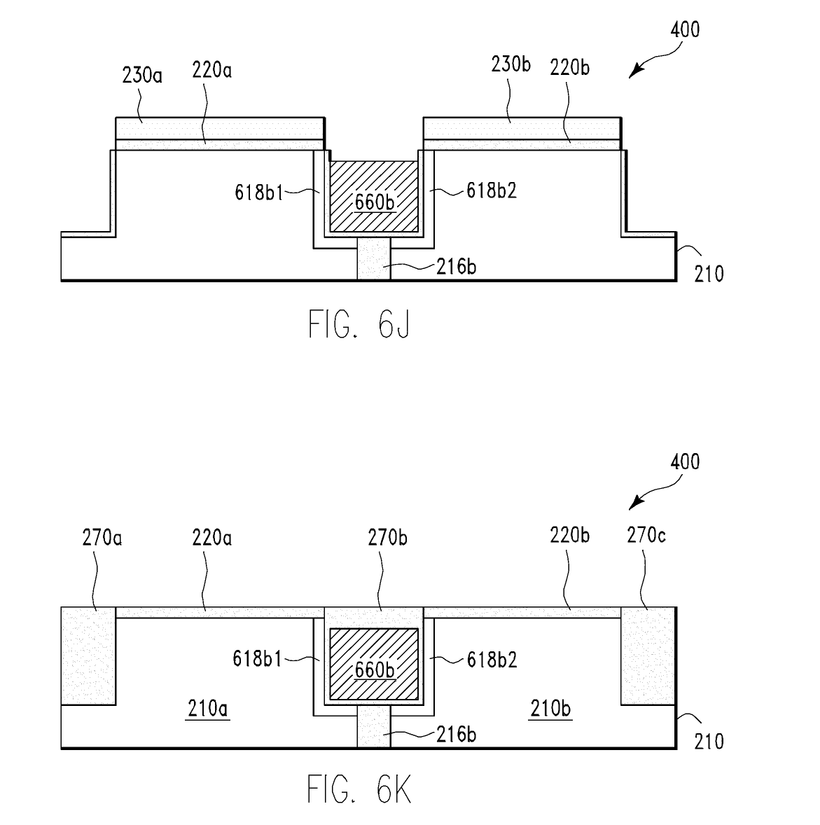

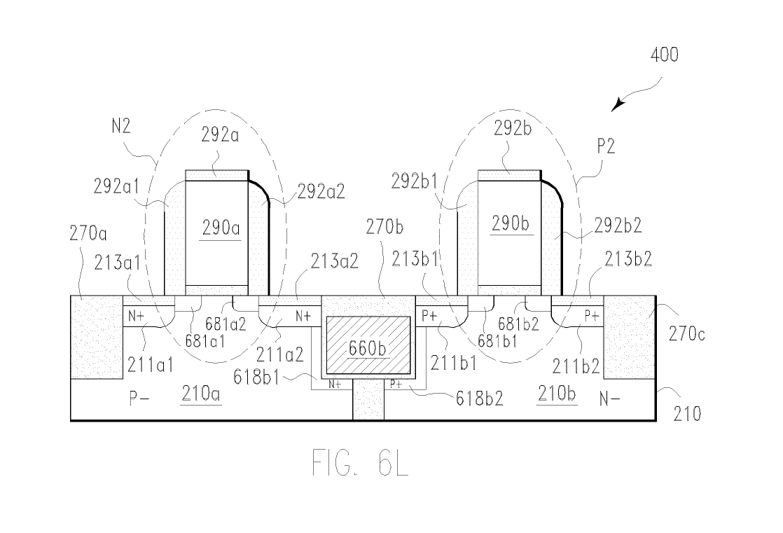

FIGS. 6A-6L show cross-section views used to illustrate a fabrication process of the digital circuit 400 of FIG. 5B, in accordance with embodiments of the present invention. More specifically, with reference to FIG. 6A, the fabrication process of the digital circuit 400 (also called structure 400) starts with the structure 400 of FIG. 6A which is similar to the structure 100 of FIG. 3B. The formation of the structure 400 of FIG. 6A is similar to the formation of the structure 100 of FIG. 3B.

Next, with reference to FIG. 6B, in one embodiment, an ASG layer 610 is formed on top of the structure 400 of FIG. 6A. The ASG layer 610 can be formed by CVD.

Next, with reference to FIG. 6C, in one embodiment, a photoresist region 620 is formed on top of the ASG layer 610 such that (i) a left half of the trench 212b is filled by the photoresist region 620 and (ii) a right half of the trench 212b and the trenches 212a and 212c are not filled by the photoresist region 620. The photoresist region 620 can be formed by a lithographic process.

Next, in one embodiment, the ASG layer 610 is etched in the vertical direction with the photoresist region 620 as a blocking mask resulting in structure 400 of FIG. 6D.

Next, in one embodiment, the photoresist region 620 is removed. The photoresist region 620 can be removed by plasma or wet etching.

Next, with reference to FIG. 6E, in one embodiment, the n-type doped region 618b1 is formed in the silicon substrate 210. The n-type doped region 618b1 can be formed by annealing the structure 400 resulting in arsenic atoms from an ASG spacer region 614 being diffused into the silicon substrate 210 resulting in the n-type doped region 618b1 on the side walls and bottom walls of the trench 212b. Next, the ASG spacer region 614 is removed resulting in the structure 400 of FIG. 6E′. The ASG spacer region 614 can be removed by wet etching.

Next, with reference to FIG. 6F, in one embodiment, a BSG layer 630 is formed on top of the structure 400 of FIG. 6E′. The BSG layer 630 can be formed by CVD.

Next, in one embodiment, a photoresist region 640 is formed on top of the BSG layer 630 such that (i) the right half of the trench 212b is filled by the photoresist region 640 and (ii) the left half of the trench 212b and the trenches 212a and 212b are not filled by the photoresist region 640. The photoresist region 640 can be formed by a lithographic process.

Next, in one embodiment, the BSG layer 630 is etched in the vertical direction with the photoresist region 640 as a blocking mask resulting in structure 400 of FIG. 6F′.

Next, in one embodiment, the photoresist region 640 is removed. The photoresist region 640 can be removed by plasma or wet etching.

Next, with reference to FIG. 6G, in one embodiment, the p-type doped region 618b2 is formed in the silicon substrate 210. The p-type doped region 618b2 can be formed by annealing the structure 400 resulting in boron atoms from a BSG spacer region 634 being diffused into the silicon substrate 210 resulting in p-type doped region 618b2 on the side walls and bottom walls of the trench 212b. Next, the BSG spacer region 634 is removed resulting in the structure 400 of FIG. 6G′. The BSG spacer region 634 can be removed by wet etching.

Next, with reference to FIG. 6H, in one embodiment, a trench 654 is formed in the silicon substrate 210. The trench 654 can be formed by lithographic and etching processes.

Next, with reference to FIG. 6I, in one embodiment, (i) dielectric regions 216a and 216c are formed on side walls and bottom walls of the trenches 212a and 212c, respectively, and (ii) a dielectric region 216b is formed in the opening 654 and on the side walls and bottom walls of the trench 212b. The dielectric regions 216a, 216b, and 216c can be formed by (i) depositing a silicon dioxide layer (not shown) on top of the structure 400 of FIG. 6H, then (ii) isotropically etching the silicon dioxide layer to clean up the side walls of the trenches 212a, 212b, and 212c, and then (iii) thermally oxidizing the side walls of the trenches 212a, 212b, and 212c followed by plasma nitridation resulting in the dielectric regions 216a, 216b, and 216c.

Next, with reference to FIG. 6I′, in one embodiment, electrically conductive regions 660a and 660c and the electrically conductive region 660b are formed in the trenches 212a, 212c, and 212b, respectively. The electrically conductive regions 660a, 660b, and 660c can be formed by a conventional method.

Next, in one embodiment, the electrically conductive regions 660a and 660c are removed resulting in the structure 400 of FIG. 6J. The electrically conductive regions 660a and 660c can be removed by lithographic and etching processes (etching the electrically conductive regions 660a and 660c while covering the electrically conductive region 660b with a photoresist region (not shown)).

Next, with reference to FIG. 6K, in one embodiment, dielectric regions 270a, 270b, and 270c are formed in the trenches 212a, 212b, and 212c, respectively. The dielectric regions 270a, 270b, and 270c can be formed by (i) depositing an oxide layer (not shown) on top of the structure 400 of FIG. 6J such that the trenches 212a, 212b, and 212c are filled and then (ii) planarizing the oxide layer until the portions of the oxide layer outside the trenches 212a, 212b, and 212c and the nitride regions 230a and 230b are removed.

Next, in one embodiment, a P-well region 210a and an N-well region 210b are formed in the silicon substrate 210. The P-well region 210a and the N-well region 210b can be formed in a manner similar to the manner in which the P-well region 210a and the N-well region 210b of FIG. 3O are formed.

Next, with reference to FIG. 6L, in one embodiment, the NFET N2 and the PFET P2 are formed on top of the P-well region 210a and the N-well region, respectively. The NFET N2 and the PFET P2 can be formed in a manner similar to the manner in which the NFET N2 and the PFET P2 of FIG. 3P are formed.

Next, in one embodiment, a dielectric layer (not shown) is formed on top of the structure 400 of FIG. 6L. Next, contact regions (including (i) the contact region Cond to conductor 660b and (ii) the contact regions OUT2a and OUT2b of FIG. 5A) are formed in the dielectric layer to provide electrical access to the silicide regions 213a1, 213a2, 213b1, 213b2, 292a, and 292b. It should be noted that the structure 400 of FIG. 6L is the same as the structure 400 of FIG. 5B except that the structure 400 of FIG. 6L has more detail.

With reference to FIG. 6L, the source/drain region 211a2 and the n-type doped region 618b1 can be collectively referred to as an N+ region 211a2+618b1. The N+ region 211a2+618b1 and the electrically conductive region 660b constitute two electrodes of the capacitor C3a. Similarly, the source/drain region 211b1 and the p-type doped region 618b2 can be collectively referred to as a P+ region 211b1+618b2. The P+ region 211b1+618b2 and the electrically conductive region 660b constitute two electrodes of the capacitor C3b.

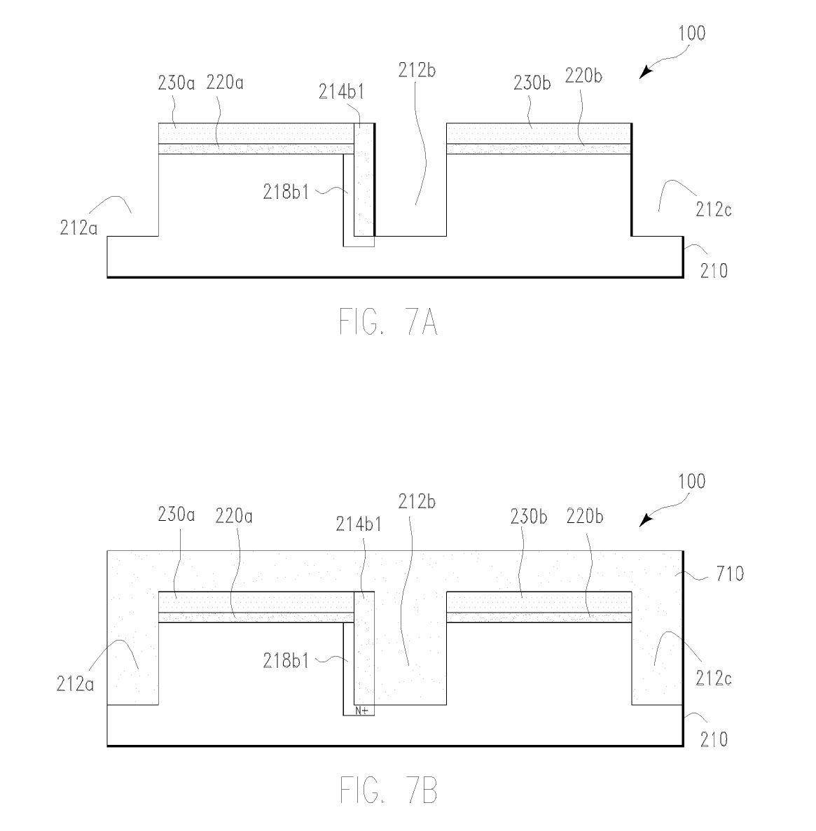

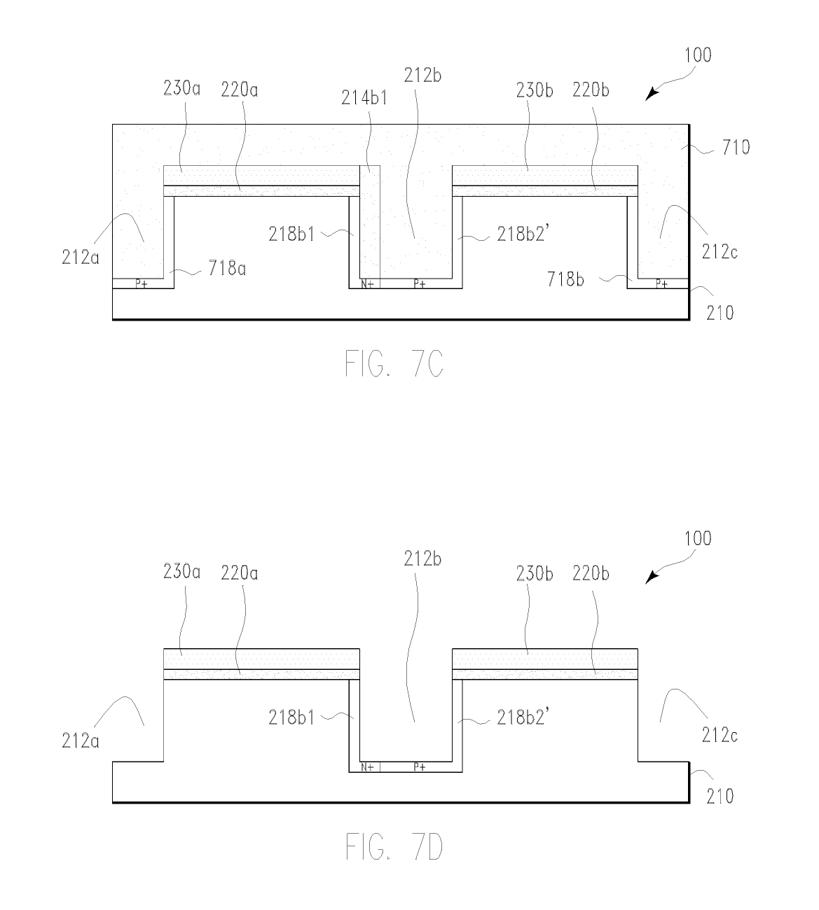

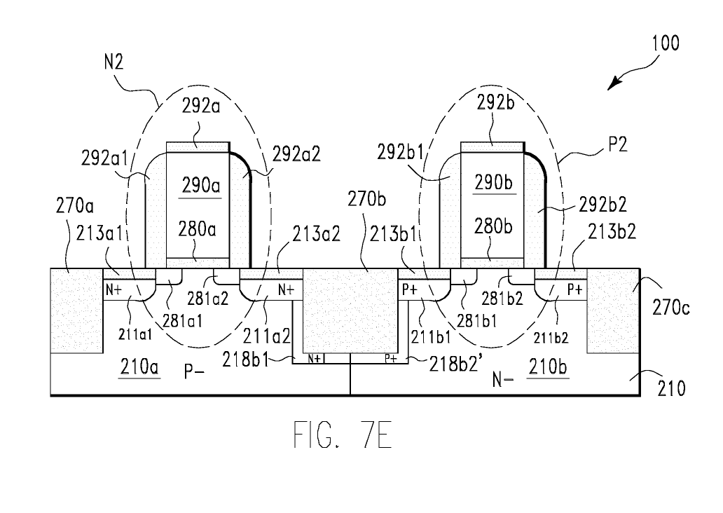

FIGS. 7A-7E show cross-section views used to illustrate another fabrication process of the digital circuit 100 of FIG. 2B, in accordance with embodiments of the present invention. More specifically, the fabrication process of the digital circuit 100 of FIG. 2B starts with the structure 100 of FIG. 7A. The structure 100 of FIG. 7A is similar to the structure 100 of FIG. 3F. The formation of the structure 100 of FIG. 7A is similar to the formation of FIG. 3F.

Next, with reference to FIG. 7B, in one embodiment, a BSG layer 710 is formed on top of the structure 100 of FIG. 7A. The BSG layer 710 can be formed using a conventional method (e.g., by depositing a conformal BSG layer on top of the structure 100 of FIG. 7A).

Next, with reference to FIG. 7C, in one embodiment, a p-type doped region 218b2′, a p-type doped region 718a, and a p-type doped region 718b are formed in the silicon substrate 210. The p-type doped regions 218b2′, 718a, and 718b can be formed by annealing the structure 100 of FIG. 7B resulting in boron atoms from the BSG layer 710 being diffused into the silicon substrate 210 resulting in the p-type doped regions 218b2′, 718a, and 718b on the side walls and bottom walls of the trenches 212b, 212a, and 212c, respectively. Next, the BSG layer 710 and the ASG spacer region 214b1 are removed. The BSG layer 710 and the ASG spacer region 214b1 can be removed by wet etching. Next, the P+ regions 718a and 718b are removed resulting in the structure 100 of FIG. 7D. The P+ regions 718a and 718b can be removed by conventional lithographic and etching processes.

Next, with reference to FIG. 7E, in one embodiment, regions similar to the regions of FIG. 3P are formed on the structure 100 of FIG. 7D in the similar manner. As a result, the structure 100 of FIG. 7E is similar to the structure 100 of FIG. 3P except that the n-type doped region 218b1 is in direct physical contact with the p-type doped region 218b2′. In one embodiment, with reference to FIG. 6G′, in one embodiment, the n-type doped region 618b1 and the p-type doped region 618b2 are formed in a manner similar to the manner in which the n-type doped region 218b1 and the p-type doped region 218b2′ of FIG. 7E are formed.

In summary, with reference to FIG. 2A, the presence of the doped regions 218b1, 218b2, 218b3, and 218b4 helps increase the capacitances of the capacitors C2a, C2b, C1b, and C1a (FIG. 1), respectively, making it more difficult for the digital circuit 100 to change from one state to another under the impact of external particles impinging on the digital circuit 100. Similarly, with reference to FIG. 5A, the presence of the doped regions 618b1, 618b2, 618b3 and 618b4 helps increase the capacitances of the capacitors C3a and C3b (FIG. 4) making it even more difficult for the digital circuit 400 to change from one state to another under the impact of external particles impinging on the digital circuit 400.

While particular embodiments of the present invention have been described herein for purposes of illustration, many modifications and changes will become apparent to those skilled in the art. Accordingly, the appended claims are intended to encompass all such modifications and changes as fall within the true spirit and scope of this invention.

What is claimed is:

1. A semiconductor structure, comprising:
(a) a semiconductor substrate;
(b) a shallow trench isolation (STI) region on the semiconductor substrate;
(c) a first semiconductor transistor on the semiconductor substrate,
wherein the first semiconductor transistor comprises (i) a first source/drain region, (ii) a second source/drain region, and (iii) a first gate electrode region, and
wherein the first and second source/drain regions are doped with a first doping polarity; and
(d) a first doped region in the semiconductor substrate,
wherein the first doped region is on a first side wall and a bottom wall of the STI region,
wherein the first doped region is in direct physical contact with the second source/drain region, and
wherein the first doped region is doped with the first doping polarity.

2. The structure of claim 1, further comprising:
(a) a second semiconductor transistor on the semiconductor substrate,
wherein the second semiconductor transistor comprises (i) a third source/drain region, (ii) a fourth source/drain region, and (iii) a second gate electrode region,
wherein the third and fourth source/drain regions are doped with a second doping polarity,
wherein the second gate electrode region is electrically coupled to the first gate electrode region, and
wherein the second source/drain region is electrically coupled to the third source/drain region; and
(b) a second doped region in the semiconductor substrate,
wherein the second doped region is on a second side wall of the STI region,
wherein the second doped region is in direct physical contact with the third source/drain region, and
wherein the second doped region is doped with the second doping polarity.

3. The structure of claim 2, wherein the second doped region is further on the bottom wall of the STI region.

4. The structure of claim 2, wherein the first doping polarity is opposite to the second doping polarity.

5. The structure of claim 2, further comprising:
(a) a third semiconductor transistor on the semiconductor substrate,
wherein the third semiconductor transistor comprises (i) a fifth source/drain region, (i) a sixth source/drain region, and (iii) a third gate electrode region, and
wherein the fifth and sixth source/drain regions are doped with the second doping polarity;
(b) a third doped region in the semiconductor substrate,
wherein the third doped region is on a third side wall of the STI region,
wherein the third doped region is in direct physical contact with the sixth source/drain region, and
wherein the third doped region and the sixth source/drain region are doped with the second doping polarity;
(c) a fourth semiconductor transistor on the semiconductor substrate,
wherein the fourth semiconductor transistor comprises (i) a seventh source/drain region, (ii) an eighth source/drain region, and (iii) a fourth gate electrode region,
wherein the seventh and eighth source/drain regions are doped with the first doping polarity,
wherein the fourth gate electrode region is electrically coupled to the third gate electrode region, and
wherein the sixth source/drain region is electrically coupled to the seventh source/drain region; and
(d) a fourth doped region in the semiconductor substrate,
wherein the fourth doped region is on a fourth side wall of the STI region,
wherein the fourth doped region is in direct physical contact with the seventh source/drain region,
wherein the fourth doped region is doped with the first doping polarity,
wherein the first gate electrode region is electrically coupled to the sixth source/drain region, and
wherein the third gate electrode region is electrically coupled to the second source/drain region.

6. The structure of claim 5, wherein the first doping polarity is opposite to the second doping polarity.

7. The structure of claim 2, further comprising an electrically conductive region on the semiconductor substrate,
wherein a first portion of the STI region (i) is sandwiched between and (ii) electrically insulates the first doped region and the electrically conductive region,
wherein a second portion of the STI region (i) is sandwiched between and (ii) electrically insulates the second doped region and the electrically conductive region, and
wherein the electrically conductive region is electrically coupled to the first gate electrode region.

8. The structure of claim 2, wherein the first and fourth source/drain regions are electrically coupled to a cathode and an anode of a power supply, respectively.

9. The structure of claim 1, wherein the STI region comprises silicon dioxide.

10. The structure of claim 1, wherein the first doped region comprises n-type dopants.

11. A semiconductor structure fabrication method, comprising:
providing a semiconductor structure which includes a semiconductor substrate and a shallow trench on the semiconductor substrate;
forming a first doped region in the semiconductor substrate; then
forming a shallow trench isolation (STI) region in the shallow trench,
wherein the first doped region is on a first side wall of the STI region; and
forming a first semiconductor transistor on the semiconductor substrate,
wherein the first semiconductor transistor comprises (i) a first source/drain region, (ii) a second source/drain region, and (iii) a first gate electrode region,
wherein the first doped region is in direct physical contact with the second source/drain region,
wherein the first and second source/drain regions are doped with a first doping polarity, and
wherein the first doped region is doped with the first doping polarity.

12. The method of claim 11, wherein the first doped region is further on a bottom wall of the STI region.

13. The method of claim 11, further comprising:
after said forming the first doped region is performed and before said forming the STI region is performed, forming a second doped region in the semiconductor substrate,
wherein the second doped region is on a second side wall and a bottom wall of the STI region; and
after said forming the STI region is performed, forming a second semiconductor transistor on the semiconductor substrate,
wherein the second semiconductor transistor comprises (i) a third source/drain region, (ii) a fourth source/drain region, and (iii) a second gate electrode region,
wherein the second doped region is in direct physical contact with the third source/drain region,
wherein the third and fourth source/drain regions are doped with a second doping polarity,
wherein the second doped region is doped with the second doping polarity,
wherein the second gate electrode region is electrically coupled to the first gate electrode region, and
wherein the second source/drain region is electrically coupled to the third source/drain region.

14. The method of claim 13, wherein the first doping polarity is opposite to the second doping polarity.

15. The method of claim 13, further comprising, after said forming the second doped region is performed and before said forming the STI region is performed, forming an electrically conductive region on the semiconductor substrate,
wherein a first portion of the STI region (i) is sandwiched between and (ii) electrically insulates the first doped region and the electrically conductive region,
wherein a second portion of the STI region (i) is sandwiched between and (ii) electrically insulates the second doped region and the electrically conductive region, and
wherein the electrically conductive region is electrically coupled to the first gate electrode region.

16. The method of claim 13, wherein said forming the second doped region comprises:
forming a dopant containing region on the second side wall and in the shallow trench; and then
annealing the semiconductor structure resulting dopants diffusing from the dopant containing region into the semiconductor substrate resulting in the second doped region.

17. The method of claim 16, wherein the dopant containing region comprises arsenic silicate glass.

18. The method of claim 16, wherein the dopant containing region comprises boron silicate glass.

19. The method of claim 11, wherein the first doped region comprises n-type dopant.

20. The method of claim 11, wherein said forming the first doped region comprises:
forming a dopant containing region on the first side wall and in the shallow trench; and then
annealing the semiconductor structure resulting dopants diffusing from the dopant containing region into the semiconductor substrate resulting in the first doped region.
